(19) United States
(12) Patent Application Publication
(10) Pub. No.: US 2015/0021074 A1
(43) Pub. Date: Jan. 22, 2015

(54) PRINTED CIRCUIT BOARD AND MANUFACTURE METHOD THEREOF

(71) Applicant: SAMSUNG ELECTRO-MECHANICS CO., LTD., Suwon (KR)

(72) Inventors: Sang Hoon KIM, Gunpo (KR); Tae Hong MIN, Suwon (KR); Jung Han LEE, Seoul (KR); Hye Jin KIM, Yongin (KR)

(21) Appl. No.: 14/298,098

(22) Filed: Jun. 6, 2014

(30) Foreign Application Priority Data
Jul. 18, 2013 (KR) 10-2013-0084775

(51) Int. Cl. H05K 1/02; H05K 1/18; H05K 1/11; H05K 3/00; H05K 3/30

(52) U.S. Cl. CPC H05K 1/0271; H05K 3/007; H05K 3/305; H05K 1/115; H05K 1/184
USPC 174/258; 29/837; 174/262

(57) ABSTRACT

Disclosed herein is a printed circuit board capable of implementing slimness by decreasing the number of entire layers through an asymmetrical build-up structure in which an electric device is embedded, the printed circuit board including: a core layer including a cavity formed therein so that an electric device is embedded and a circuit pattern and a pad formed on upper and lower surfaces thereof; a through via formed in the core layer so as to connect the upper and the lower pads of the core layer to each other; a plurality of insulating layers built-up on the core layer and including a plurality of vias so as to be electrically connected to the through via; and a solder resist layer applied onto a lower portion of the core layer so that a lower surface of the through via is partially exposed.

### CROSS REFERENCE(S) TO RELATED APPLICATIONS

This application claims the benefit under 35 U.S.C. Section 119 of Korean Patent Application Serial No. 10-2013-0084775, entitled “Printed Circuit Board and Manufacturing Method Thereof” filed on Jul. 18, 2013, which is hereby incorporated by reference in its entirety into this application.

### BACKGROUND OF THE INVENTION

1. Technical Field

The present invention relates to a printed circuit board and a manufacturing method thereof, and more particularly, to a printed circuit board capable of implementing slimness by decreasing the entire number of layers through an asymmetrical build-up structure in which an electric device is embedded, and a manufacturing method thereof.

2. Description of the Related Art

In accordance with the trends toward lightness, miniaturization, high-speed, multi-functionality, high performance of electronic products, an embedded printed circuit board (embedded PCB) technology of embedding a device in a printed circuit board (PCB) has been developed.

At the time of implementing the embedded PCB, the most important technology is to enable electric conduction after performing an embedding process through package of the device.

At the time of manufacturing a PCB for embedding devices, in order to embed the device on a core layer, after a through hole such as a cavity is formed and a heat-resistance dust-free tape is attached to one surface of a core board for temporarily fixing the device to embed the electric device, an insulating layer is laminated, and then the dust-free tape is removed.

Thereafter, an insulating layer is laminated again on the surface to which the tape was attached and a hole is formed therein, and then the device and the board are electrically connected to each other by plating. A circuit pattern is formed on a plating surface, and a printed circuit board including the electric device embedded therein is manufactured using a manufacturing process of a multilayer printed circuit board.

However, in the printed circuit board manufactured as described above, as the insulating layer is uniformly laminated on both surfaces of the core layer embedded with the device, the entire thickness of the printed circuit board becomes thick, which does not satisfy the recent trends toward slimness of electronic products.

### RELATED ART DOCUMENT

### [Patent Document]

(Patent Document 1) Cited Document: Japanese Patent Laid-Open Publication No. 2007-227976

### SUMMARY OF THE INVENTION

An object of the present invention is to provide a printed circuit board capable of implementing slimness of the entire thickness of the board by asymmetrically laminating an insulating layer based on a core layer embedded with an electric device.

Another object of the present invention is to provide a printed circuit board capable of minimizing warpage generated due to an asymmetrically laminated insulating layer and warpage generated during an embedding process of the electric device through a configuration in which solder resists on upper and lower surfaces of a core layer or each layer of copper layers have difference thicknesses with each other.

According to an exemplary embodiment of the present invention, there is provided a printed circuit board including: a core layer including a cavity formed therein so that an electric device is embedded and a circuit pattern and a pad formed on upper and lower surfaces thereof; a through via formed in the core layer so as to connect the upper and the lower pads of the core layer to each other; a plurality of insulating layers built-up on the core layer and including a plurality of vias so as to be electrically connected to the through via; and a solder resist layer applied onto a lower surface of the core layer so that a lower surface of the through via is partially exposed.

A solder resist of the solder resist layer may be partially filled between the electric device and the cavity.

A resin of the insulating layer may be partially filled between the electric device and the cavity.

The solder resist of the solder resist layer and the resin of the insulating layer may be partially filled between the electric device and the cavity at the same time.

A solder resist may be applied onto an upper surface of the insulating layer so as to have a thickness relatively thinner than that of the solder resist layer on the lower surface of the core layer.

A lower pattern of the core layer may have a thickness relatively thicker than that of an upper pattern thereof.

The insulating layer may be configured by laminating a plurality of layers in which a resin is impregnated in glass fabric.

In the insulating layer, the plurality of layers having different thicknesses from each other may be laminated.

According to another exemplary embodiment of the present invention, there is provided a manufacturing method of a printed circuit board, the manufacturing method including: providing a core layer including a cavity formed therein and a pattern and a through via formed on upper and lower surfaces thereof; attaching a double-sided tape to one surface of the core layer and disposing an electric device in the cavity; attaching the core layer attached with the double-sided tape to both side surfaces of a carrier; building-up a plurality of layers on the core layer attached to the carrier to manufacture a printed circuit board; separating the build-up printed circuit board from the carrier; separating the double-sided tape from the separated printed circuit board; and applying a solder resist onto a lower surface of the core layer from which the double-sided tape is separated so that the through via is partially exposed.

The uppermost layer of the plurality of built-up layers may be applied with a solder resist having a thickness relatively thinner than that of the solder resist on the lower surface of the core layer.

### BRIEF DESCRIPTION OF THE DRAWINGS

FIG. 1 is an exemplary view showing a printed circuit board according to an exemplary embodiment of the present invention.

FIG. 2 is an exemplary view showing a printed circuit board according to another exemplary embodiment of the present invention.

FIG. 3 is an exemplary view showing a state in which a lower pad of a core is formed to have a thickness thicker than that of an upper portion in the printed circuit board according to the exemplary embodiment of the present invention.

FIG. 4 is an exemplary view showing a state in which a plurality of layers having different thicknesses from each other are configured in the printed circuit board according to the exemplary embodiment of the present invention.

FIGS. 5A to 5D are exemplary views showing a manufacturing method of a printed circuit board according to the exemplary embodiment of the present invention.

### DESCRIPTION OF THE PREFERRED EMBODIMENTS

Hereinafter, preferable embodiments of the present invention will be described in detail with reference to the accompanying drawings.

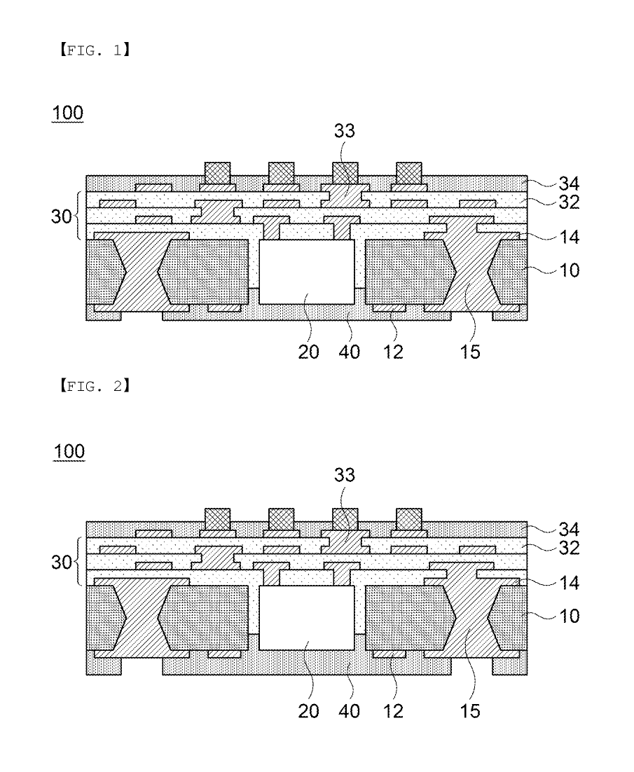

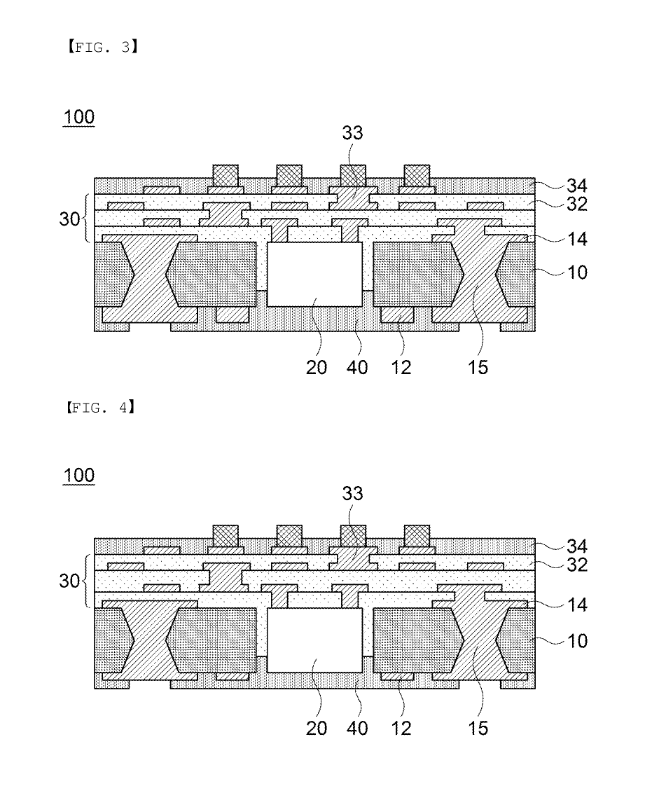

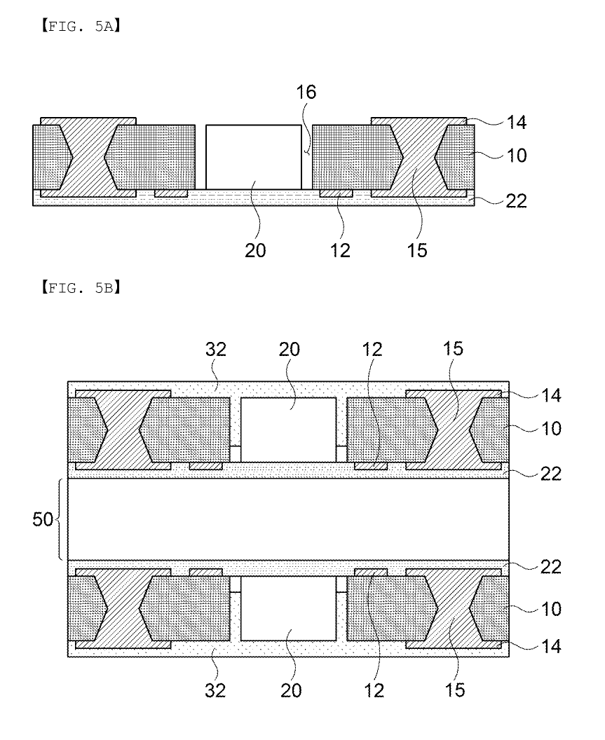

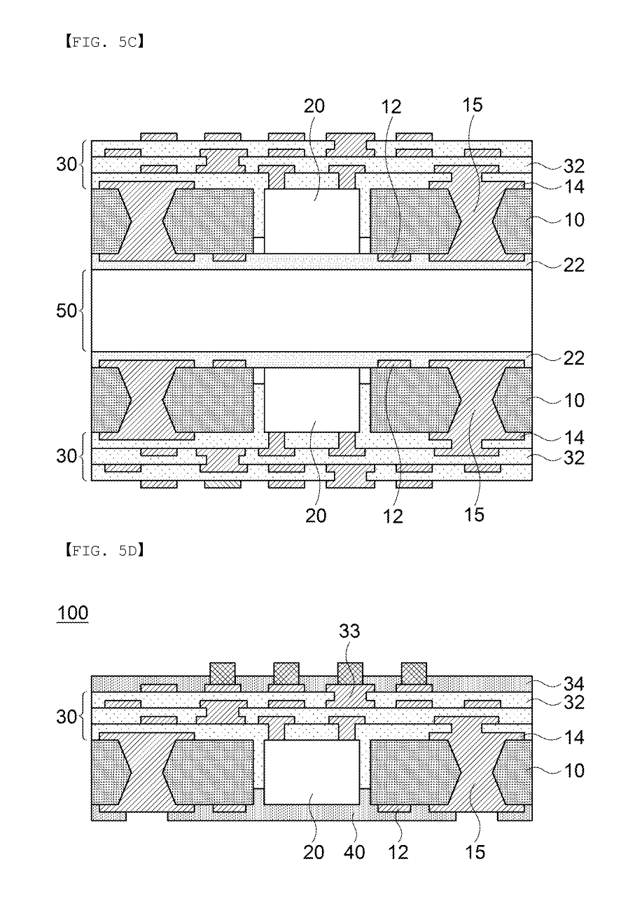

FIG. 1 is an exemplary view showing a printed circuit board according to an exemplary embodiment of the present invention; FIG. 2 is an exemplary view showing a printed circuit board according to another exemplary embodiment of the present invention; FIG. 3 is an exemplary view showing a state in which a lower pad of a core is formed to have a thickness thicker than that of an upper portion in the printed circuit board according to the exemplary embodiment of the present invention; FIG. 4 is an exemplary view showing a state in which a plurality of layers having different thicknesses from each other are configured in the printed circuit board according to the exemplary embodiment of the present invention; and FIGS. 5A to 5D are exemplary views showing a manufacturing method of a printed circuit board according to the exemplary embodiment of the present invention.

As shown in FIGS. 1 to 4, a printed circuit board 100 according to the exemplary embodiment of the present invention may include a core layer 10 embedded with an electric device 20, a through via 15 formed in the core layer 10, an insulating layer 30 laminated so as to be built up on the core layer 10, and a solder resist layer 40 applied on the a lower surface of the core layer 10 so that the through via 15 is partially exposed.

The core layer 10 may be made of an insulating material such as a resin. Although not shown in the accompanying drawings, the core layer 10 may also be manufactured in a shape in which glass fabric is included therein so as to increase a modulus.

Upper and lower surfaces of this core layer 10 may be provided with a copper clad layer made of copper, respectively, and this copper clad layer is formed as a circuit pattern 12 and a pad 14 by etching.

Here, the circuit pattern 12 and the pad 14 formed on each of the upper and lower surfaces of the core layer 10, may be configured so that the upper and lower surfaces have the same thickness as each other, but the lower surface of the core layer 10 may have a thickness thicker than that of the upper surface thereof in order to minimize warpage of the board, or according to the design.

In addition, a cavity 16 configured of a through hole having a standard size larger than that of the electric device 20 is formed in the core layer 10 so that the electric device 20 may be embedded therein. The cavity 16 may have a sufficient standard size so that the electric device 20 may be received therein.

Both sides of the cavity 16 may be formed with through vias 15 so as to connect the pads 14 formed on the upper and lower surfaces of the core layer 10 to each other. The through via 15 may be manufactured in a linear shape having a predetermined width or a sandglass shape.

The insulating layer 30 may be built-up on the core layer 10. The insulating layer 30 may include a plurality of laminated layers 32 and contain an insulating film material such as glass fabric or a build-up film so as to minimize warpage of the board due to a difference in thermal expansion coefficient.

That is, the insulating layer 30 may have a shape in which a resin is impregnated in the glass fabric so as to increase the modulus or be configured of only the insulating film such as the build-up film without containing the glass fabric.

In addition, a plurality of vias 33 may be formed in the insulating layer 30 so as to allow layers to be conducted to each other. The plurality of vias 33 may be concentrated on both sides to which the electric device 20 is installed so as to allow layers to be conducted to each other while minimizing warpage of the board.

In this case, as another example for minimizing the warpage of the board, a plurality of layers 32 may have different thicknesses from each other. In other words, warpage that may be generated during a process of configuring the insulating layer 30 may be minimized by laminating and arranging the layers 32 so as to have different thicknesses from each other in consideration of thermal expansion coefficients of the layers 32 to be built-up.

In addition, a solder resist 34 for protecting the layer 32 may be applied onto the uppermost layer of the insulating layer 30.

Meanwhile, at the time of configuring the insulating layer 30, the resin may be partially introduced and filled a space between the electric device 20 embedded in the core layer 10 and the cavity 16. In the case in which the resin is filled between the cavity 16 and the electric device 20, mobility of the electric device 20 is limited, such that even though external impact is generated, an installation state may be firmly maintained.

In addition, the lower surface of the core layer 10 may be provided with the solder resist layer 40 so that the through via 15 is partially exposed as it is.

The solder resist layer 40 may be formed to have a relatively thicker thickness than that of the solder resist 34 applied onto the uppermost portion of the insulating layer 30. When the solder resist layer 40 is applied so as to be thicker than the solder resist 34 applied onto the uppermost surface of the insulating layer, warpage of the plurality of layers 32 laminated on the core layer 10 may be effectively restricted.

In this case, during a process of forming the solder resist layer 40, the solder resist may be partially filled between the cavity 16 of the core layer and the electric device 20. An amount of solder resist filled between the cavity 16 of the core layer and the electric device 20 may be significantly small but play a significantly important role in allowing the electric device 20 not to move in the cavity 16.

Further, the solder resist may be filled in the cavity 16 up to a position in which the resin of the insulating layer 30 is filled.

That is, the resin of the insulating layer 30 is filled from the upper surface approximately up to a central position of the electric device 20, and the solder resist is filled from the lower surface up to a position at which the resin is not filled based on the core layer 10.

A process for manufacturing the printed circuit board according to the present invention configured as described above will be described below with reference to FIGS. 5A to 5D.

A circuit pattern 12 and a through via 15 are formed in a core layer 10, and a cavity 16 is formed in the core layer using a laser or a drill of a machining center so that an electric device 20 is embedded therein.

After the cavity 16 is punched in the core layer 10, the electric device 20 is disposed by attaching a double-sided tape 22 onto lower surface of the core layer 10 so that the electric device 20 is not separated from the core layer 10.

When the electric device 20 is disposed in the cavity 16 of the core layer 10 through the double-sided tape 22, the core layers 10 are attached to both side surfaces of a carrier 50.

When the core layers 10 are attached to both side surfaces of the carrier 50 through the double-sided tape 22, respectively, a plurality of layers are built-up on the core layer 10.

When the plurality of layers 32 are built-up to thereby configure an insulating layer 30, the core layers 10 are separated from the both side surfaces of the carrier 50 and the double-sided tape 22 is separated therefrom.

Next, the uppermost layer 32 of the insulating layer is applied with a solder resist 34, and a lower surface of the core layer 10 is also formed with a solder resist layer 40 so that a lower surface of the through via 15 is exposed.

In this case, the solder resist layer 40 on a lower surface of the core layer 10 is applied so as to maintain a relatively thicker thickness than that of the solder resist 34 on an upper surface of the insulating layer 30, such that warpage of the board may be minimized.

As described above, in the printed circuit board 100 according to the exemplary embodiment of the present invention, as the insulating layer 30 is built-up in an asymmetrical shape based on the core layer 10, the entire thickness may be slim, and generation of warpage of the board may be minimized due to the thickness difference between each of layers 32 configuring the insulating layer 30 and the thickness difference of the pad 14.

The printed circuit board according to the exemplary embodiment of the present invention may implement slimness of the entire thickness of the board by asymmetrically laminating the insulating layer based on the core layer embedded the electric device.

In addition, the generation of the warpage caused by the asymmetrically laminated insulating layer and the heat generated by the electric device may be minimized through the configuration in which thicknesses of the solder resists on the upper and lower surfaces of the core layer or each layer of the copper layer are different from each other, such that even in the case of manufacturing the slimmed board, the reliability of the product may be secured.

Hereinabove, although the printed circuit board according to the exemplary embodiment of the present invention is described, the present invention is not limited thereto, but may be variously modified and altered by those skilled in the art.

1. A printed circuit board comprising:
a core layer including a cavity formed therein so that an electric device is embedded and a circuit pattern and a pad formed on upper and lower surfaces thereof;
a through via formed in the core layer so as to connect the upper and the lower pads of the core layer to each other;
a plurality of insulating layers built-up on the core layer and including a plurality of vias so as to be electrically connected to the through via; and
a solder resist layer applied onto a lower portion of the core layer so that a lower surface of the through via is partially exposed.

2. The printed circuit board according to claim 1, wherein a solder resist of the solder resist layer is partially filled between the electric device and the cavity.

3. The printed circuit board according to claim 1, wherein a resin of the insulating layer is partially filled between the electric device and the cavity.

4. The printed circuit board according to claim 2, wherein the solder resist of the solder resist layer and the resin of the insulating layer are partially filled between the electric device and the cavity.

5. The printed circuit board according to claim 1, wherein a solder resist is applied onto an upper surface of the insulating layer so as to have a thickness relatively thinner than that of the solder resist layer on the lower portion of the core layer.

6. The printed circuit board according to claim 1, wherein a lower pattern of the core layer has a thickness relatively thicker than that of an upper pattern thereof.

7. The printed circuit board according to claim 1, wherein the insulating layer is configured by laminating a plurality of layers in which a resin is impregnated in glass fabric.

8. The printed circuit board according to claim 1, wherein in the insulating layer, the plurality of layers having different thicknesses from each other are laminated.

9. A manufacturing method of a printed circuit board, the manufacturing method comprising:
providing a core layer including a cavity formed therein and a pattern and a through via formed on upper and lower surfaces thereof;
attaching a double-sided tape to one surface of the core layer and disposing an electric device in the cavity;
attaching the core layer attached with the double-sided tape to both side surfaces of a carrier;
building-up a plurality of layers on the core layer attached to the carrier to manufacture a printed circuit board;
separating the build-up printed circuit board from the carrier;
separating the double-sided tape from the separated printed circuit board; and
applying a solder resist onto a lower surface of the core layer from which the double-sided tape is separated so that the through via is partially exposed.

10. The manufacturing method according to claim 9, wherein the uppermost layer of the plurality of built-up layers is applied with a solder resist having a thickness relatively thinner than that of the solder resist on the lower portion of the core layer.

11. The printed circuit board according to claim 3, wherein the solder resist of the solder resist layer and the resin of the insulating layer are partially filled between the electric device and the cavity.
